(19) United States
(12) Patent Application Publication
(10) Pub. No.: US 2026/0136574 A1
(43) Pub. Date: May 14, 2026

(54) SEMICONDUCTOR DEVICE AND MANUFACTURING METHOD

(71) Applicant: FUJI ELECTRIC CO., LTD., Kanagawa (JP)

(72) Inventor: Yasuyuki HOSHI, Matsumoto-city (JP)

(21) Appl. No.: 19/334,925

(22) Filed: Sep. 21, 2025

(30) Foreign Application Priority Data
Nov. 12, 2024 (JP) 2024-197752

(51) Int. Cl. H10D 12/00; H10D 12/01; H10D 62/10; H10D 62/60; H10D 64/23

(52) U.S. Cl. CPC H10D 12/481; H10D 12/038; H10D 62/102; H10D 62/126; H10D 62/60; H10D 64/2527

(57) ABSTRACT

Provided is a semiconductor device including: a trench contact portion in which, compared to a cross-sectional area at a first depth position, a cross-sectional area at a second depth position farther from an upper surface than the first depth position is smaller; a first emitter portion of a first conductivity type which is provided between a side wall of the trench contact portion and a trench portion; a second emitter portion of the first conductivity type which is provided below the first emitter portion and has a doping concentration lower than that of the first emitter portion; and a side wall region of a second conductivity type which is provided between the side wall of the trench contact portion and the second emitter portion.

The contents of the following patent application(s) are incorporated herein by reference: No. 2024-197752 filed in JP on Nov. 12, 2024.

### BACKGROUND

### 1. Technical Field

The present invention relates to a semiconductor device and a manufacturing method.

### 2. Related Art

Paragraph 0119 of Patent Document 1 describes that “in the present example, the doping concentration of the P type diffusion region 16 is higher than the doping concentration of the P type base region 14. The P type diffusion region 16 may have a concentration peak having a doping concentration higher than that of the P type base region 14. In order to form the P type diffusion region 16, it is preferable to perform ion implantation obliquely”. Paragraph 0040 of Patent Document 2 discloses “performing the first oblique ion implantation 32 at a shallow depth d1 with respect to the side wall 8b of the contact trench 8”. Paragraph 0021 of Patent Document 3 discloses that “the side wall of the body contact trench (second trench) 8 has an inclined portion that connects the vicinity of the upper end portion of the first trench 4 and the bottom portion of the body contact trench (second trench) 8 located deeper than the upper surface of the gate electrode”. Paragraph 0075 of Patent Document 4 describes that “the contact trench 52 is formed deeper than the p well region 26. The contact trench 52 is formed such that a first inclination angle (“θ1” in FIG. 3) of the side surface of the contact trench 52 with respect to the first surface is 60 degrees or more and 85 degrees or less”. Paragraph 0048 of Patent Document 5 describes that “the source region 104 includes a first source subregion 1041 directly adjacent to the contact 112 in the source contact zone 113 of the first surface 110. The source region 104 further includes a second source subregion 1042 and a third source subregion 1043”.
Patent Document 1: Japanese Patent Application Publication No. 2023-128635
Patent Document 2: Japanese Patent Application Publication No. 2018-110166
Patent Document 3: Japanese Patent Application Publication No. 2011-134985
Patent Document 4: Japanese Patent Application Publication No. 2018-14455
Patent Document 5: Japanese Patent Application Publication No. 2020-145430

### BRIEF DESCRIPTION OF THE DRAWINGS

FIG. 1 is a top view illustrating an example of a semiconductor device 100.

FIG. 2 is an example of an enlarged view of a region D in FIG. 1.

FIG. 3 is a view illustrating an example of a cross section taken along line a-a in FIG. 2.

FIG. 4 is an enlarged view of a cross section in a vicinity of a mesa portion 60.

FIG. 5 is a view illustrating an example of a doping concentration distribution taken along line h-h in FIG. 4.

FIG. 6 is a view illustrating another example of the doping concentration distribution taken along line h-h.

FIG. 7 is a view illustrating another example of the doping concentration distribution taken along line h-h.

FIG. 8 is a view illustrating another structure example of the mesa portion 60.

FIG. 9 is a view illustrating a partial process of a manufacturing process of the semiconductor device 100.

FIG. 10 is a view illustrating an example of a method of forming a contact trench 220.

FIG. 11 is a view illustrating another structure example of the mesa portion 60.

FIG. 12 is a view illustrating another structure example of the mesa portion 60.

FIG. 13 is a view illustrating another structure example of the mesa portion 60.

FIG. 14 is a view illustrating another example of steps S410 to S430 of forming a trench contact portion 210, a side wall region 86, and a bottom region 87.

FIG. 15 is a view illustrating another structure example of the mesa portion 60.

FIG. 16 is a view illustrating an example of collector voltage-collector current characteristics of the semiconductor device 100.

### DESCRIPTION OF EXEMPLARY EMBODIMENTS

The present invention will be described below through embodiments of the invention, but the following embodiments do not limit the invention according to the claims. In addition, not all combinations of features described in the embodiments are essential to a solution of the invention.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in implementation of a semiconductor device.

In the present specification, technical matters may be described by using orthogonal coordinate axes of an X axis, a Y axis, and a Z axis. The orthogonal coordinate axes merely specify relative positions of components, and do not limit a particular direction. For example, the Z axis is not limited to indicate a height direction with respect to the ground. It is to be noted that a +Z axis direction and a-Z axis direction are directions opposite to each other. When a Z axis direction is described without describing a sign, it means that the direction is parallel to a +Z axis and a-Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, a direction of the Z axis may be referred to as the depth direction. In addition, in the present specification, a direction parallel to the upper surface and the lower surface of the semiconductor substrate may be referred to as a horizontal direction, including an X axis direction and a Y axis direction.

A region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a p type or an n type. In the present specification, the impurity may particularly mean either a donor of the n type or an acceptor of the p type, and may be described as a dopant. In the present specification, doping means introducing the donor or the acceptor into the semiconductor substrate and turning it into a semiconductor presenting a conductivity type of the n type, or a semiconductor presenting a conductivity type of the p type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}−N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. In the present specification, the VOH defect may be referred to as a hydrogen donor.

In the present specification, a description of a P+ type or an N+ type means a higher doping concentration than that of the P type or the N type, and a description of a P-type or an N-type means a lower doping concentration than that of the P type or the N type. In the present specification, a conductivity type indicated by lowercase p or n, such as the p type or the n type, does not indicate a relative magnitude of the doping concentration. In the present specification, a unit system is an SI unit system unless otherwise noted. Although a unit of a length may be expressed in cm, various calculations may be performed after conversion to meters (m).

A chemical concentration in the present specification refers to an atomic density of an impurity measured regardless of an electrical activation state. The chemical concentration (atomic density) can be measured by, for example, secondary ion mass spectrometry (SIMS). The net doping concentration described above can be measured by capacitance-voltage profiling (CV profiling). In addition, a carrier concentration measured by spreading resistance profiling (SRP method) may be set as the net doping concentration. The carrier concentration measured by the CV profiling or the SRP method may be a value in a thermal equilibrium state. In addition, in a region of the n type, the donor concentration is sufficiently higher than the acceptor concentration, and thus the carrier concentration of the region may be set as the donor concentration. Similarly, in a region of the p type, the carrier concentration of the region may be set as the acceptor concentration. In the present specification, the doping concentration of the n type region may be referred to as the donor concentration, and the doping concentration of the p type region may be referred to as the acceptor concentration.

When a concentration distribution of the donor, acceptor, or net doping has a peak in a region, a value of the peak may be defined as the concentration of the donor, acceptor, or net doping in the region. In a case where the concentration of the donor, acceptor or net doping is substantially uniform in a region, or the like, an average donor, acceptor or net doping concentration in the region may be defined as a donor, acceptor or net doping concentration. In the present specification, atoms/cm³ or/cm³ is used to express a concentration per unit volume. This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in the carrier mobility occurs when carriers are scattered due to disorder of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron serving as an acceptor is approximately 99% of chemical concentrations of these. On the other hand, in the silicon semiconductor, a donor concentration of hydrogen serving as a donor is approximately 0.1% to 10% of a chemical concentration of hydrogen. Each concentration in the present specification may be a value at room temperature. As an example, a value at 300K (Kelvin) (substantially 26.9 degrees C.) may be used for a value at room temperature.

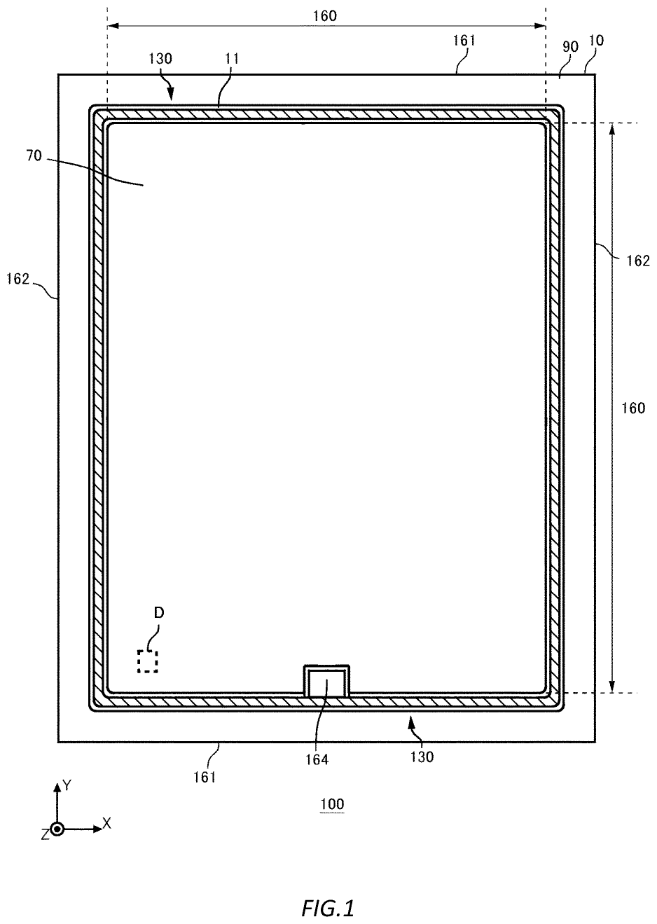

FIG. 1 illustrates a top view illustrating an example of a semiconductor device 100. FIG. 1 illustrates a position at which each member is projected on an upper surface of a semiconductor substrate 10. FIG. 1 illustrates only some members of the semiconductor device 100, and illustration of some members is omitted.

The semiconductor device 100 includes the semiconductor substrate 10. The semiconductor substrate 10 is a substrate which is formed of a semiconductor material. Although the semiconductor substrate 10 is a silicon substrate by way of example, the material of the semiconductor substrate 10 is not limited to silicon. The semiconductor substrate 10 may be a wide band gap substrate formed of a material having a band gap larger than that of silicon. For example, the semiconductor substrate 10 may be a compound semiconductor substrate such as a SiC substrate or a GaN substrate.

The semiconductor substrate 10 has a first end side 161 and a second end side 162 in a top view. In the present specification, unless otherwise specified, a top view means a view from the upper surface side of the semiconductor substrate 10. The semiconductor substrate 10 of the present example has two sets of first end sides 161 facing each other in a top view. In addition, the semiconductor substrate 10 of the present example has two sets of second end sides 162 facing each other in a top view. In FIG. 1, the first end side 161 is parallel to the X axis direction. The second end side 162 is parallel to the Y axis direction. In addition, the Z axis is perpendicular to the upper surface of the semiconductor substrate 10. In addition, the first end sides 161 are perpendicular to an extending direction or a longitudinal direction of a gate trench portion which will be described below. The second end sides 162 are parallel to the extending direction or the longitudinal direction of the gate trench portion which will be described below.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but illustration thereof is omitted in FIG. 1.

In the present example, the active portion 160 is provided with a transistor portion 70 including a transistor element such as an IGBT. In another example, the transistor portion 70 and a diode portion including a diode element such as a free wheel diode (FWD) may be alternately arranged along a predetermined array direction on the upper surface of the semiconductor substrate 10. Although one transistor portion 70 is provided in the present example, a plurality of transistor portions 70 may also be provided. A well region of the P+ type or a gate runner may be provided between the transistor portions 70.

The transistor portion 70 includes a collector region of the P+ type in a region in contact with the lower surface of the semiconductor substrate 10. In addition, in the transistor portion 70, an emitter region of the N+ type, a base region of the P-type, a drift region of the N-type, and a surface MOS structure having a gate conductive portion, and a gate dielectric film are periodically arranged on the upper surface side of the semiconductor substrate 10.

The semiconductor device 100 may include one or more pads above the semiconductor substrate 10. The semiconductor device 100 of the present example includes a gate pad 164.

The semiconductor device 100 may include a pad such as an anode pad, a cathode pad, and a current detection pad. Each pad is arranged in a vicinity of the first end side 161. The vicinity of the first end side 161 refers to a region between the first end side 161 and the emitter electrode in a top view. In implementation of the semiconductor device 100, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate wiring line 130 that connects the gate pad 164 and the gate trench portion. In FIG. 1, the gate wiring line 130 is hatched with diagonal lines.

The gate wiring line 130 is arranged between the active portion 160 and the first end side 161 or the second end side 162 in a top view. The gate wiring line 130 of the present example encloses the active portion 160 in a top view. A region enclosed by the gate wiring line 130 in a top view may be the active portion 160. In addition, the gate wiring line 130 is connected to the gate pad 164. The gate wiring line 130 is arranged above the semiconductor substrate 10. The gate wiring line 130 may be a metal wiring including aluminum or the like. The gate wiring line 130 may be provided separate from the emitter electrode.

A p type outer circumferential well region 11 is provided so as to overlap the gate wiring line 130. That is, similarly to the gate wiring line 130, the p type outer circumferential well region 11 encloses the active portion 160 in a top view. The p type outer circumferential well region 11 is provided so as to extend with a predetermined width also in a range not overlapping the gate wiring line 130. The p type outer circumferential well region 11 is a region of a second conductivity type. The p type outer circumferential well region 11 of the present example is of the P+ type. A doping concentration of the p type outer circumferential well region 11 may be 5.0×10¹⁷ atoms/cm³ or more and 5.0×10¹⁹ atoms/cm³ or less. The doping concentration of the p type outer circumferential well region 11 may be 2.0×10¹⁸ atoms/cm³ or more and 2.0×10¹⁹ atoms/cm³ or less.

The semiconductor device 100 may include a temperature sensing unit (not illustrated) which is a pn junction diode formed of polysilicon or the like, and a current detection unit (not illustrated) which simulates an operation of the transistor portion 70 provided in the active portion 160. The temperature sensing unit may be connected to the anode pad and the cathode pad via a wiring. When the temperature sensing unit is provided, the temperature sensing unit is preferably provided at a center of the semiconductor substrate 10 in the X axis direction and the Y axis direction.

The semiconductor device 100 of the present example includes an edge termination structure portion 90 between the active portion 160 and the first end side 161 or the second end side 162 in a top view. The edge termination structure portion 90 of the present example is arranged between the outer circumferential gate wiring line 130 and the first end side 161 or the second end side 162. The edge termination structure portion 90 reduces electric field strength on the upper surface side of the semiconductor substrate 10. The edge termination structure portion 90 may include at least one of a guard ring, a field plate, or a RESURF which are annularly provided enclosing the active portion 160.

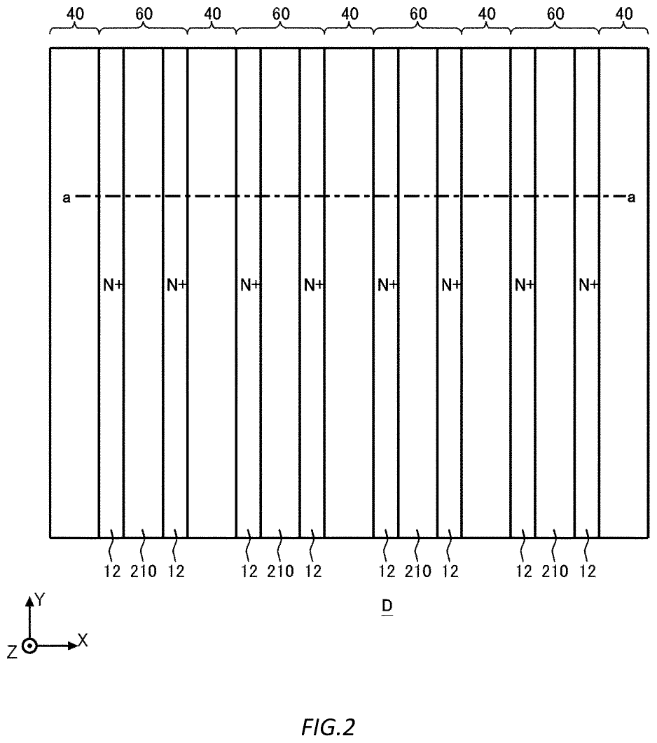

FIG. 2 is an example of an enlarged view of a region D in FIG. 1. The region D is a region which includes the transistor portion 70 of the active portion 160 illustrated in FIG. 1. FIG. 2 illustrates a structure of the upper surface of the semiconductor substrate 10 in the region D. In the region D, the semiconductor device 100 includes a plurality of gate trench portions 40 and a plurality of mesa portions 60.

The plurality of gate trench portions 40 are provided side by side in a first direction at the upper surface of the semiconductor substrate 10. The first direction of the present example is the X axis direction. The gate trench portions 40 are arrayed at predetermined intervals in the X axis direction. Each gate trench portion 40 is provided at the upper surface of the semiconductor substrate 10 to extend in a second direction intersecting the first direction. That is, the gate trench portion 40 is elongated in the second direction at the upper surface of the semiconductor substrate 10. The second direction of the present example is the Y axis direction. Each gate trench portion 40 is provided from the upper surface to an inside of the semiconductor substrate 10.

The gate trench portion 40 is a trench portion to which a gate potential is applied. A gate conductive portion formed of a conductive material such as polysilicon is arranged inside the gate trench portion 40. The gate conductive portion is electrically connected to the gate wiring line 130 (see FIG. 1), and a predetermined gate voltage is applied thereto. A part of the gate trench portion 40 illustrated in FIG. 2 may be replaced with a dummy trench portion. The dummy trench portion is a trench portion to which a potential of the emitter electrode is applied. The dummy trench portion has a structure similar to that of the gate trench portion. A trench portion adjacent to the gate trench portion 40 in the X axis direction may be the dummy trench portion. One or more dummy trench portions may be arranged between two gate trench portions 40. However, the gate trench portions 40 may be arranged adjacent to each other in the X axis direction.

A region of the semiconductor substrate 10 sandwiched between two trench portions in the X axis direction is defined as a mesa portion 60. Each end of the mesa portion 60 in the X axis direction is a boundary portion with each trench portion. A depth position of a lower end of the mesa portion 60 is to be the same as a depth position of a lower end of at least one of the trench portions on both sides.

An emitter region 12 and a trench contact portion 210 are provided in at least one mesa portion 60. The emitter region 12 and the trench contact portion 210 may be provided in at least one mesa portion 60 in contact with the gate trench portion 40, the emitter region 12 and the trench contact portion 210 may be provided in all mesa portions 60 in contact with the gate trench portion 40, or the emitter region 12 and the trench contact portion 210 may be provided in all mesa portions 60.

The emitter region 12 is a region of the N+ type provided to be exposed on the upper surface of the semiconductor substrate 10. The emitter region 12 of the present example is in contact with the gate trench portion 40. Each emitter region 12 may have a band shape extending in the Y axis direction. The emitter region 12 may be provided in each of the gate trench portions 40 sandwiching the mesa portion 60. In a portion in contact with the gate trench portion 40, one emitter region 12 extending in the Y axis direction may be provided in one mesa portion 60. In another example, a plurality of emitter regions 12 discretely arranged in the Y axis direction may be provided in a portion in contact with the gate trench portion 40. In this case, a contact region of the P+ type may be provided between two emitter regions 12 in the Y axis direction. That is, the emitter region 12 and the contact region may be alternately arranged in the Y axis direction.

The trench contact portion 210 is provided from the upper surface to the inside of the semiconductor substrate 10 in the mesa portion 60. The trench contact portion 210 may be provided at the upper surface of the semiconductor substrate 10 to extend in the Y axis direction. That is, the trench contact portion 210 may be elongated in the Y axis direction at the upper surface of the semiconductor substrate 10. The trench contact portion 210 has a structure in which a trench provided in the mesa portion 60 is filled with a conductive material. An emitter potential is applied to the conductive material. The trench contact portion 210 is not in contact with the trench portion. In the present example, the emitter region 12 is provided between the trench contact portion 210 and the trench portion. The above-described contact region may also be provided in a partial region between the trench contact portion 210 and the trench portion.

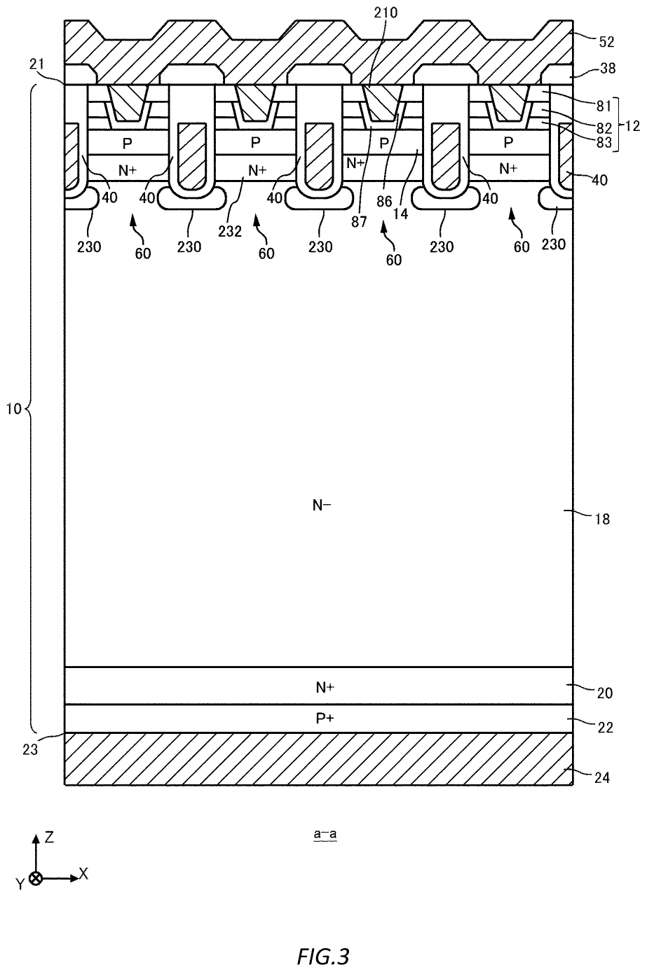

FIG. 3 is a view illustrating an example of a cross section taken along line a-a in FIG. 2. A cross section a-a is an XZ cross section passing through the emitter region 12 and the trench contact portion 210. In the cross section, the semiconductor device 100 of the present example includes the semiconductor substrate 10, an interlayer dielectric film 38, an emitter electrode 52, and a collector electrode 24.

The semiconductor substrate 10 has an upper surface 21 and a lower surface 23. The upper surface 21 and the lower surface 23 are two principal surfaces having a largest area among surfaces of the semiconductor substrate 10. A drift region 18 of the n type is provided inside the semiconductor substrate 10.

The emitter electrode 52 is provided above the upper surface 21 of the semiconductor substrate 10. A part of the upper surface 21 of the semiconductor substrate 10 is covered with the interlayer dielectric film 38. The emitter electrode 52 is in contact with at least a part of the upper surface 21 of the semiconductor substrate 10 that is not covered with the interlayer dielectric film 38. The emitter electrode 52 of the present example is in contact with the emitter region 12 and the trench contact portion 210.

The emitter electrode 52 is formed of a material including metal. For example, at least a partial region of the emitter electrode 52 is formed of aluminum or an aluminum-silicon alloy, for example, a metal alloy such as AlSi or AlSiCu. The emitter electrode 52 may have a barrier metal formed of titanium, titanium nitride, or the like below a region formed of aluminum or the like. The barrier metal may be in contact with the semiconductor substrate 10.

The interlayer dielectric film 38 is provided on the upper surface 21 of the semiconductor substrate 10. The interlayer dielectric film 38 is a film including at least one layer of a dielectric film such as silicate glass to which an impurity such as boron or phosphorous is added, a thermal oxide film, or other dielectric films. The interlayer dielectric film 38 may cover each trench portion. The interlayer dielectric film 38 may be provided inside the trench portion.

The collector electrode 24 is provided on the lower surface 23 of the semiconductor substrate 10. Similarly to the emitter electrode 52, the collector electrode 24 is formed of a metal material such as aluminum. In the present specification, a direction in which the emitter electrode 52 is connected to the collector electrode 24 (Z axis direction) is referred to as the depth direction.

A plurality of mesa portions 60 are provided on the upper surface 21 side of the semiconductor substrate 10. The emitter region 12, the trench contact portion 210, a side wall region 86, a bottom region 87, and a base region 14 are provided in each mesa portion 60. Each configuration of the mesa portion 60 will be described below.

A plurality of gate trench portions 40 are provided at the upper surface 21 of the semiconductor substrate 10. Each gate trench portion 40 is provided from the upper surface 21 to the inside of the semiconductor substrate 10. The gate trench portion 40 of the present example penetrates the base region 14 from the upper surface 21 and reaches the drift region 18. A structure in which the trench portion penetrates the doping region is not limited to a structure which is made by forming the doping region and then forming the trench portion in order. A structure in which the trench portion is formed and then the doping region is formed between the trench portions is also included in the structure in which the trench portion penetrates the doping region.

The gate trench portion 40 includes a groove-shaped gate trench, a gate dielectric film 42, and a gate conductive portion 44 which are provided at the upper surface 21 of the semiconductor substrate 10. The gate conductive portion 44 is formed of polysilicon which is a conductive material. The gate dielectric film 42 is provided to cover an inner wall of the gate trench. The gate dielectric film 42 may be formed by oxidizing or nitriding a semiconductor on the inner wall of the gate trench. The gate conductive portion 44 is provided on an inner side further than the gate dielectric film 42 inside the gate trench. That is, the gate dielectric film 42 insulates the gate conductive portion 44 from the semiconductor substrate 10.

The gate conductive portion 44 in the gate trench portion 40 may be provided longer than the base region 14 in the depth direction. The gate trench portion 40 in the cross section is covered with the interlayer dielectric film 38 on the upper surface 21 of the semiconductor substrate 10. The gate conductive portion 44 is electrically connected to the gate wiring line 130 at a position other than the cross section illustrated in FIG. 3.

A lower end region 230 may or may not be provided in contact with a lower end of each gate trench portion 40. The lower end region 230 is a region of the p type. The lower end region 230 may be provided so as to cover a lowermost surface of the gate trench portion 40. The lower end region 230 is arranged separately from the base region 14. Providing the lower end region 230 can reduce electric field strength at the lower end of the gate trench portion 40. The lower end region 230 may be provided across a plurality of gate trench portions 40.

The semiconductor substrate 10 of the present example includes the drift region 18 of the N-type. The emitter region 12 has a higher doping concentration than the drift region 18. The drift region 18 is provided below the base region 14. The drift region 18 may be in contact with the base region 14. In another example, an accumulation region 232 of the N+ type having a doping concentration higher than that of the drift region 18 may be provided between the drift region 18 and the base region 14, or may not be provided. Providing the accumulation region 232 can produce an electron injection enhancement effect to decrease an ON voltage of the semiconductor device 100.

A collector region 22 of the P+ type is provided between the drift region 18 and the lower surface 23 of the semiconductor substrate 10. A doping concentration of the collector region 22 is higher than a doping concentration of the base region 14. The collector region 22 may include an acceptor which is the same as or different from an acceptor of the base region 14. The acceptor of the collector region 22 is, for example, boron. The element serving as the acceptor is not limited to the example described above. The collector region 22 is exposed on the lower surface 23 of the semiconductor substrate 10 and is connected to the collector electrode 24. The collector electrode 24 may be in contact with the entire lower surface 23 of the semiconductor substrate 10. As described above, when a diode portion is provided in the active portion 160, the diode portion may be provided with a cathode region of the N+ type instead of the collector region 22.

A buffer region 20 of the N+ type may be provided between the drift region 18 and the collector region 22. A doping concentration of the buffer region 20 is higher than a doping concentration of the drift region 18. The buffer region 20 may have one or more concentration peaks with a doping concentration higher than that of the drift region 18. A doping concentration at a concentration peak refers to a doping concentration at a local maximum of the concentration peak. In addition, as the doping concentration of the drift region 18, an average value of doping concentrations in a region where a doping concentration distribution is substantially flat may be used.

The buffer region 20 may be formed by ion implantation of the dopant of the n type such as hydrogen (proton) or phosphorous. The buffer region 20 of the present example is formed by the ion implantation of hydrogen. The buffer region 20 may function as a field stopper layer which prevents a depletion layer expanding from a lower end of the base region 14 from reaching the collector region 22.

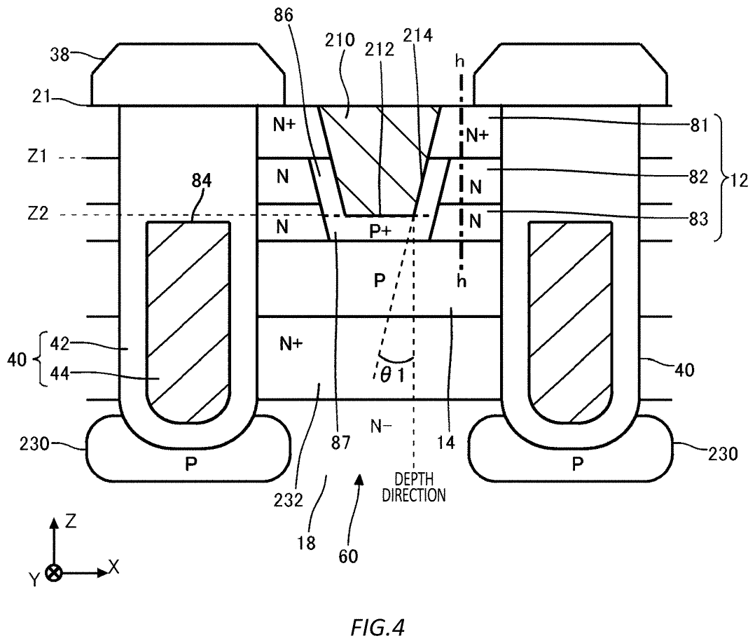

FIG. 4 is an enlarged view of a cross section in a vicinity of the mesa portion 60. As described above, the emitter region 12, the trench contact portion 210, the side wall region 86, the bottom region 87, and the base region 14 are provided in the mesa portion 60. Below the base region 14 in the mesa portion 60, the drift region 18 of the N-type may be provided, and the accumulation region 232 of the n type having a concentration higher than that of the drift region 18 may be provided.

The trench contact portion 210 is provided from the upper surface 21 to the inside of the semiconductor substrate 10 in the mesa portion 60. The trench contact portion 210 of the present example is a plug formed of a conductive material such as tungsten. The trench contact portion 210 may be formed of a material different from that of the emitter electrode 52. A depth position (that is, a position in the Z axis direction) of a boundary between the trench contact portion 210 and the emitter electrode 52 may coincide with or may not coincide with the upper surface 21 of the semiconductor substrate 10.

The trench contact portion 210 has a bottom portion 212 and a side wall 214. The bottom portion 212 is a portion arranged at a lowermost part in the trench contact portion 210.

The bottom portion 212 may be a plane parallel to the XY plane. In the trench contact portion 210, a portion within a predetermined distance in the depth direction from the portion arranged at the lowermost part may be defined as the bottom portion 212. The predetermined distance may be 0.1 μm, 0.2 μm, or 0.5 μm. The side wall 214 is a portion extending from the bottom portion 212 to the upper surface 21 of the semiconductor substrate 10 in the boundary of the trench contact portion 210 in the XZ cross section.

The emitter region 12 of the present example includes a first emitter portion 81 and a second emitter portion 82. The emitter region 12 may further include a third emitter portion 83. The first emitter portion 81 is a region of the n type which is provided between the side wall 214 of the trench contact portion 210 and the trench portion in the mesa portion 60. The first emitter portion 81 of the present example is a region of the N+ type having a concentration higher than that of the drift region 18. The first emitter portion 81 is connected to at least one of the emitter electrode 52 or the trench contact portion 210. In the example of FIG. 4, the first emitter portion 81 is connected to both the emitter electrode 52 and the trench contact portion 210. The first emitter portion 81 may be in contact with a side surface of the gate trench portion 40.

The second emitter portion 82 is provided below the first emitter portion 81 between the side wall 214 of the trench contact portion 210 and the trench portion. The second emitter portion 82 of the present example is a region of the N type having a doping concentration lower than that of the first emitter portion 81. The second emitter portion 82 is provided in contact with the first emitter portion 81. The second emitter portion 82 may be in contact with the side surface of the gate trench portion 40. The second emitter portion 82 of the present example is not in contact with the emitter electrode 52.

The side wall region 86 is a region of the p type which is provided between the side wall 214 of the trench contact portion 210 and the second emitter portion 82. The side wall region 86 of the present example is in contact with the side wall 214 of the trench contact portion 210. The side wall region 86 may be a region of the P+ type having a concentration higher than that of the base region 14. The doping concentration of the side wall region 86 may be 10 times or more, 50 times or more, or 100 times or more the doping concentration of the base region 14.

The side wall region 86 of the present example is provided so as to cover an entire side surface of the second emitter portion 82 facing the side wall 214 in the X axis direction. That is, the second emitter portion 82 is not in contact with the trench contact portion 210.

The first emitter portion 81 includes a region that does not face the side wall region 86 in the X axis direction. That is, the side wall region 86 is not provided at at least a part of a side surface of the first emitter portion 81 facing the side wall 214 in the X axis direction. The side wall region 86 may not be provided in an entire region between the side wall 214 and the first emitter portion 81. The first emitter portion 81 of the present example is in contact with the side wall 214 of the trench contact portion 210. The entire side surface of the first emitter portion 81 may be in contact with the side wall 214.

By providing the side wall region 86, a total current flowing between the second emitter portion 82 and the emitter electrode 52 passes through the first emitter portion 81. In addition, a total current flowing between the first emitter portion 81 and the base region 14 passes through the second emitter portion 82.

The second emitter portion 82 of the present example has a doping concentration lower than that of the first emitter portion 81. This increases a resistance value of the second emitter portion 82. In addition, a current flowing between the first emitter portion 81 and the base region 14 passes through the second emitter portion 82. Therefore, by providing the second emitter portion 82, a resistance of the emitter region 12 can be increased.

By increasing the resistance of the emitter region 12, it is possible to achieve both a relatively low saturation current and a relatively low ON voltage. A MOS structure provided at the upper surface 21 of the semiconductor substrate 10 has a saturation characteristic in which a collector current is saturated even when a voltage between a collector and an emitter is increased. Accordingly, the semiconductor device 100 has a short-circuit withstand characteristic in which an element is not destroyed within a certain period of time in a short-circuit state in which a high current and a high voltage are simultaneously applied. When the MOS structure is formed in all the mesa portions 60 in a state where device miniaturization has progressed, a saturation current becomes extremely high, and thus, there is a case where the saturation current is suppressed by a thinned structure in which the MOS structure is not formed in some mesa portions 60, a ladder structure in which the emitter regions 12 elongated in the X axis direction are discretely arranged in the Y axis direction, or the like. However, when the saturation current is suppressed with such a structure, the ON voltage becomes high.

A current saturation characteristic of the MOS structure is expressed by following Expression 1.

$$Isat = \frac{Z μ nCox}{Lch} [ \frac{1}{2} {( V ge - V th )}^{2} ] \qquad Expression 1$$

Isat represents a saturation current, Z represents a total emitter width of the emitter region 12 (that is, a total length in the Y axis direction), un represents electron mobility, Cox represents a capacitance of the gate dielectric film 42, Lch represents a channel length in the Z axis direction, Vge represents a gate-emitter voltage, and Vth represents a threshold voltage.

A channel resistance Rch of the MOS structure is expressed by following Expression 2.

$$Rch = \frac{Lch}{Z μ nCox ( V ge - V th )} \qquad Expression 2$$

Comparison between Expressions 1 and 2 shows that decreasing the saturation current Isat increases the channel resistance Rch, and increasing the saturation current Isat decreases the channel resistance Rch. That is, when the saturation current is decreased to improve short-circuit withstand capability of the semiconductor device 100, the ON voltage is increased, which is a trade-off correlation. For example, in the thinned emitter structure, the emitter region 12 is formed in some of the mesa portions 60, and thus supply of an electron current to the drift region 18 becomes sparse in the X axis direction, causing an uneven current flow and an increase in the ON voltage. In addition, in the ladder structure in which the emitter regions 12 elongated in the X axis direction are discretely arranged in the Y axis direction, it is difficult to increase a length Z (corresponding to a channel width) along which the gate trench portion 40 and the emitter region 12 are in contact with each other.

In this regard, in the semiconductor device 100, the second emitter portion 82 is provided to suppress the saturation current. When the semiconductor device 100 is turned on, a current flows between the emitter electrode 52 and the emitter region 12 via the second emitter portion 82. Therefore, a potential of the emitter region 12 changes according to a magnitude of a current flowing through the second emitter portion 82. Since a current flows from the emitter region 12 to the emitter electrode 52, when the current flowing through the second emitter portion 82 is larger, the potential of the emitter region 12 becomes higher. When the current flowing through the second emitter portion 82 is small, the potential of the emitter region 12 increases only slightly.

Since the ON voltage applied to the gate conductive portion 44 is substantially a constant voltage, when the current flowing through the second emitter portion 82 increases, a potential difference between the gate conductive portion 44 and the emitter region 12 decreases, and a voltage applied to the gate dielectric film 42 decreases. On the other hand, when the current flowing through the second emitter portion 82 is small, the voltage applied to the gate dielectric film 42 becomes relatively large. Therefore, a saturation current flowing through the MOS structure can be suppressed.

In the semiconductor device 100, by providing the emitter region 12 elongated in the Y axis direction, the total emitter width Z can be increased and the ON voltage can be reduced. Accordingly, it is possible to achieve both a low saturation current and a low ON voltage.

In the trench contact portion 210 of the present example, a cross-sectional area at a second depth position Z2 farther from the upper surface 21 than a first depth position Z1 is smaller than a cross-sectional area at the first depth position Z1. A width of the trench contact portion 210 in the X axis direction may be treated as the cross-sectional area. The side wall 214 of the trench contact portion 210 may include an oblique portion extending in a direction intersecting the depth direction between the first depth position Z1 and the second depth position Z2. Accordingly, the cross-sectional area at the first depth position Z1 can be made larger than the cross-sectional area at the second depth position Z2. The side wall 214 between the first depth position Z1 and the second depth position Z2 may be formed partially or entirely as an oblique portion. In the example of FIG. 4, the side wall 214 is formed entirely as an oblique portion. That is, the trench contact portion 210 in FIG. 4 has a tapered shape in which the cross-sectional area increases toward the upper surface 21.

The second depth position Z2 may be below an upper end of the second emitter portion 82. The second depth position may be a lower end position of the second emitter portion 82. The first depth position Z1 may be arranged in a range from the upper end of the second emitter portion 82 to an upper end of the first emitter portion 81. The first depth position Z1 may be an upper end position of the second emitter portion 82.

In the trench contact portion 210, by making the cross-sectional area at the first depth position Z1 larger than the cross-sectional area at the second depth position Z2, it is possible to suppress a variation in the doping concentration of the side wall region 86 between the first depth position Z1 and the second depth position Z2. For example, the side wall region 86 can be formed by forming a trench for forming the trench contact portion 210 and then implanting dopant ions of the p type into the trench from above. When the side wall 214 is only a vertical portion, if a minute deviation occurs in an implantation direction of dopant ions, an implantation amount of dopant ions implanted per unit area of the side wall 214 fluctuates, and the doping concentration of the side wall region 86 varies. In this regard, the side wall 214 has an oblique portion or a stepped portion, so that it is possible to suppress a variation in the implantation amount of dopant ions with respect to the portion. Therefore, the doping concentration of the side wall region 86 can be accurately controlled. Accordingly, it is possible to suppress variations in characteristics such as a collector voltage-collector current characteristic when the mesa portion 60 is turned on.

An angle formed between the oblique portion of the side wall 214 and the depth direction is defined as θ1. The angle θ1 may be greater than or equal to 5 degrees. The angle θ1 may be 10 degrees or more, 15 degrees or more, or 20 degrees or more. By increasing the angle θ1, it is possible to suppress a variation in the implantation amount of dopant ions with respect to the side wall 214. On the other hand, when the angle θ1 is increased, the width of the trench contact portion 210 at the upper surface 21 of the semiconductor substrate 10 increases, and it becomes difficult to miniaturize the mesa portion 60. The angle θ1 may be 45 degrees or less, 40 degrees or less, 35 degrees or less, or 30 degrees or less. As the angle of the oblique portion of the side wall 214, an angle of a straight line may be used, the straight line connecting the side wall 214 at the upper end of the second emitter portion 82 and the side wall 214 at the lower end of the second emitter portion 82.

A lower end of the trench contact portion 210 may be in contact with the bottom region 87 of the p type. Similarly to the side wall region 86, the bottom region 87 can also be formed by forming a trench for forming the trench contact portion 210 and then implanting dopant ions of the p type into the trench from above. The bottom region 87 may be a region of the P+ type having a concentration higher than that of the base region 14. A doping concentration of the bottom region 87 may be 2 times or more, 5 times or more, 10 times or more, 50 times or more, or 100 times or more the doping concentration of the base region 14.

The trench contact portion 210 is provided from the upper surface 21 of the semiconductor substrate 10 to a position deeper than the lower end of the second emitter portion 82. The bottom region 87 is in contact with the base region 14. Providing the high-concentration bottom region 87 can reduce a contact resistance between the trench contact portion 210 and the base region 14.

The side wall region 86 may be a region having a concentration higher than that of the base region 14. A doping concentration of the side wall region 86 may be 2 times or more, 5 times or more, 10 times or more, 50 times or more, or 100 times or more the doping concentration of the base region 14. The bottom region 87 may be a region having a concentration higher than that of the side wall region 86. A doping concentration of the bottom region 87 may be 2 times or more, 5 times or more, or 10 times or more a doping concentration of the side wall region 86.

The third emitter portion 83 is provided below the second emitter portion 82 between the side wall 214 of the trench contact portion 210 and the trench portion. The third emitter portion 83 is a region of the N type having a doping concentration higher than that of the second emitter portion 82. The third emitter portion 83 is provided in contact with the second emitter portion 82. The third emitter portion 83 may have a doping concentration lower than that of the first emitter portion 81. The third emitter portion 83 may be in contact with a side surface of the trench portion. The third emitter portion 83 of the present example is not in contact with the emitter electrode 52.

By providing the third emitter portion 83, the second emitter portion 82 can be prevented from being in direct contact with the base region 14. Therefore, a dopant of the base region 14 can be suppressed from diffusing into the second emitter portion 82 having a low concentration, and a length of the second emitter portion 82 in the depth direction can be accurately controlled. Therefore, it is possible to suppress a variation in the resistance value in the second emitter portion 82.

The side wall region 86 of the present example is also provided between the side wall 214 of the trench contact portion 210 and the third emitter portion 83. Accordingly, the third emitter portion 83 is not in contact with the trench contact portion 210.

An upper end 84 of the gate conductive portion 44 of the gate trench portion 40 is preferably arranged to face the third emitter portion 83 in the X axis direction. The upper end 84 of the gate conductive portion 44 may refer to an upper end of a side wall of the gate conductive portion 44. The upper end 84 and the third emitter portion 83 facing each other means that the upper end 84 is arranged between an upper end position and a lower end position of the third emitter portion 83 in the Z axis direction. The upper end and the lower end of the third emitter portion 83 may refer to an upper end and a lower end of its portion in contact with a side wall of the gate trench portion 40.

When the ON voltage is applied to the gate conductive portion 44, electrons are attracted to a region of the mesa portion 60 that faces the gate conductive portion 44, in a boundary portion between the mesa portion 60 and the trench portion. When the second emitter portion 82 and the gate conductive portion 44 are arranged to face each other, electrons are also attracted to a boundary portion of the second emitter portion 82. Since the second emitter portion 82 has a low doping concentration, a resistance value at the boundary portion may fluctuate due to the attracted electrons. In this regard, the third emitter portion 83 is arranged to face the upper end 84 of the gate conductive portion 44, whereby it is possible to suppress the fluctuation in the resistance value at the boundary portion of the second emitter portion 82. In addition, since the third emitter portion 83 has a high doping concentration, even if electrons are attracted to a boundary portion of the third emitter portion 83, the fluctuation in the resistance value of the boundary portion is extremely small.

Each mesa portion 60 is provided with the base region 14 of the P-type. The base region 14 is in contact with the gate trench portion 40. The base region 14 may be in contact with each of trench portions on both sides of the mesa portion 60. At least a portion of the base region 14 is provided below the emitter region 12. The base region 14 may be in contact with the emitter region 12. When a predetermined ON voltage is applied to the gate trench portion 40, a surface layer of the base region 14 in contact with the gate trench portion 40 is inverted to a region of the n type to form a channel. The emitter region 12 is electrically connected by the channel to a drift region 18 which will be described below.

The base region 14 is also provided below the trench contact portion 210. The base region 14 may be in contact with the trench contact portion 210 or may be in contact with the bottom region 87. A doping concentration of the base region 14 may be 5.0×10¹⁶ atoms/cm³ or more and 1.0×10¹⁸ atoms/cm³ or less.

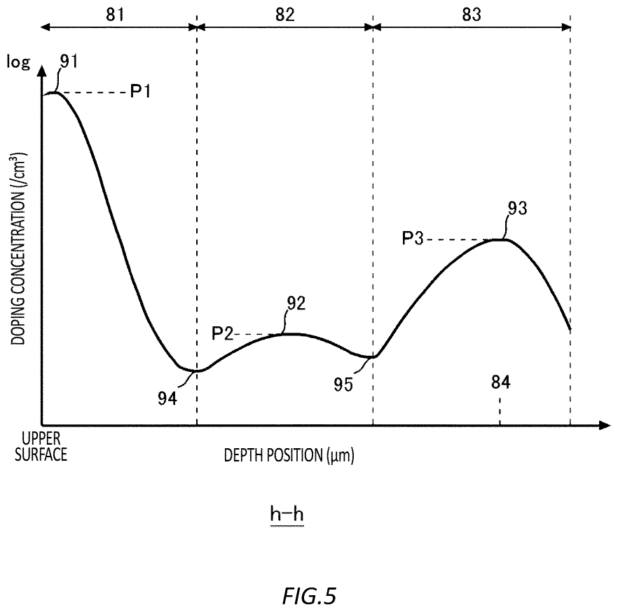

FIG. 5 is a view illustrating an example of a doping concentration distribution taken along line h-h in FIG. 4. Line h-h is a line that passes through the first emitter portion 81, the second emitter portion 82, and the third emitter portion 83 and is parallel to the Z axis.

The first emitter portion 81 of the present example has a peak 91 of the doping concentration distribution in the depth direction. The peak of the doping concentration distribution is a mountain-shaped portion showing a local maximum value at a local maximum. A doping concentration at the local maximum of the peak is defined as a doping concentration of the peak. The doping concentration of the peak 91 is defined as P1. Note that the doping concentration of the first emitter portion 81 may continuously increase from the boundary with the second emitter portion 82 to the upper surface 21 of the semiconductor substrate 10. In this case, the doping concentration of the first emitter portion 81 at the upper surface 21 is defined as P1.

The second emitter portion 82 of the present example has a peak 92 of the doping concentration distribution in the depth direction. The doping concentration of the peak 92 is defined as P2. Between the first emitter portion 81 and the second emitter portion 82, a valley portion 94 in which the doping concentration shows a local minimum value is defined as a boundary between the first emitter portion 81 and the second emitter portion 82.

The third emitter portion 83 of the present example has a peak 93 of the doping concentration distribution in the depth direction. The doping concentration of the peak 93 is defined as P3. Between the second emitter portion 82 and the third emitter portion 83, a valley portion 95 in which the doping concentration shows a local minimum value is defined as a boundary between the second emitter portion 82 and the third emitter portion 83.

As described above, the concentration P2 of the peak 92 of the second emitter portion 82 is lower than the concentration P1 of the peak 91 of the first emitter portion 81. The concentration P2 may be 1/100 times or less, or 1/1000 times or less the concentration P1. The concentration P2 may be 10 times or less or 5 times or less the doping concentration of the valley portion 94. The concentration P2 is higher than the doping concentration of the drift region 18. The concentration P2 may be 100 times or less, 10 times or less, or 5 times or less the doping concentration of the drift region 18. A resistance value in a resistor portion can be adjusted by adjusting the concentration P2.

The length of the second emitter portion 82 in the depth direction may be 2 μm or less. The length may be 1.5 μm or less or 1 μm or less. The length may be 0.1 μm or more, or 0.5 μm or more. A length of the entire emitter region 12 in the depth direction may be 3 μm or less.

The emitter region 12 of the present example can be formed by implanting dopant ions of the n type into each position of the peak 91, the peak 92, and the peak 93. The length of the second emitter portion 82 can be adjusted by depth positions forming the peak 91 and the peak 93. The resistance value in the resistor portion can be adjusted by adjusting the length of the second emitter portion 82.

As described above, the concentration P3 of the peak 93 of the third emitter portion 83 is higher than the concentration P2 of the peak 92 of the second emitter portion 82. The concentration P3 may be 10 times or more, 50 times or more, or 100 times or more the concentration P2. The concentration P3 of the peak 93 of the third emitter portion 83 may be less than or equal to the concentration P1 of the peak 91 of the first emitter portion 81. The concentration P3 may be ½ times or less, ⅕ times or less, or 1/10 times or less the concentration P1.

As described in FIG. 4, a depth position of the upper end 84 of the gate conductive portion 44 is included in a depth range in which the third emitter portion 83 is provided. The upper end 84 may be provided within a range of a full width at half maximum of the peak 93. A range of the full width at half maximum of the peak 93 is a range in which the doping concentration is half or more of P3 at the peak 93.

A length of the third emitter portion 83 in the depth direction may be 0.4 μm or more. Accordingly, even when the depth position of the upper end 84 of the gate conductive portion 44 fluctuates due to a manufacturing variation or the like, the upper end 84 can be arranged at a position facing the third emitter portion 83. The length of the third emitter portion 83 in the depth direction may be 1 μm or less. The third emitter portion 83 is only required to be able to absorb a variation in the depth position of the upper end 84. A total length of the emitter region 12 can be reduced by setting the length of the third emitter portion 83 to 1 μm or less.

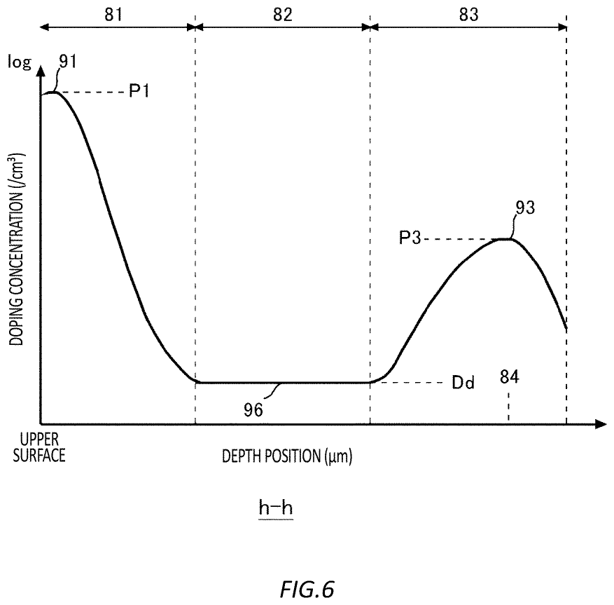

FIG. 6 is a view illustrating another example of the doping concentration distribution taken along line h-h. In the doping concentration distribution of the present example, a distribution in the second emitter portion 82 is different from that of the example of FIG. 6. Distributions in the first emitter portion 81 and the third emitter portion 83 are similar to those in the example of FIG. 5.

The second emitter portion 82 of the present example has a flat portion 96 having a flat doping concentration distribution in the depth direction. For example, the flat portion 96 is a portion in which a maximum value of the doping concentration is 2 times or less a minimum value of the doping concentration. A length of the flat portion 96 in the depth direction may be 0.1 μm or more, or 0.5 μm or more.

The minimum value of the doping concentration of the flat portion 96 may be 10 times or less, 5 times or less, or 2 times or less a doping concentration Dd. The minimum value of the doping concentration of the flat portion 96 may be the same as the doping concentration Dd of the drift region 18. In the present example, dopant ions of the n type are not implanted into the second emitter portion 82.

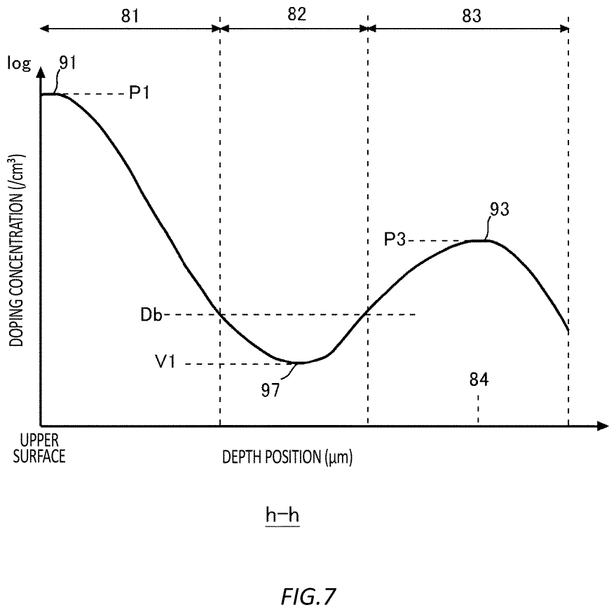

FIG. 7 is a view illustrating another example of the doping concentration distribution taken along line h-h. In the doping concentration distribution of the present example, the distribution in the second emitter portion 82 is different from that of the example of FIG. 5. The distributions in the first emitter portion 81 and the third emitter portion 83 are similar to those in the example of FIG. 5.

The second emitter portion 82 of the present example has a valley portion 97 in which the doping concentration exhibits a local minimum value in the depth direction. The local minimum value of the doping concentration in the valley portion 97 is defined as V1. The concentration V1 may be 100 times or less, 50 times or less, 10 times or less, or 5 times or less the doping concentration Dd of the drift region 18. The concentration V1 may be the same as the concentration Dd. In the present example, dopant ions of the n type are not implanted into the second emitter portion 82. The valley portion 97 in a vicinity of a boundary between the first peak 91 and the third peak 93 functions as the second emitter portion 82.

A doping concentration at both ends of the second emitter portion 82 in the depth direction is defined as Db. The concentration Db may be 10 times, 5 times, or another value of the concentration V1. The length of the second emitter portion 82 in the depth direction is similar to that in the example of FIG. 5 or 6.

The second emitter portion 82 has any one of the peak 92 shown in FIG. 5, the flat portion 96 shown in FIG. 6, or the valley portion 97 shown in FIG. 7. The second emitter portion 82 may be provided with two or more of the peak 92, the flat portion 96, or the valley portion 97.

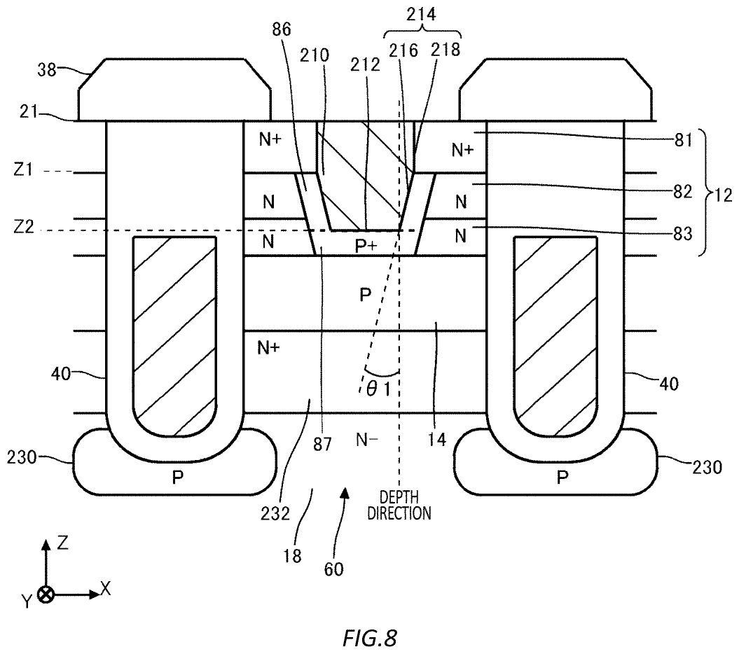

FIG. 8 is a view illustrating another structure example of the mesa portion 60. FIG. 8 is an enlarged view of the cross section in the vicinity of the mesa portion 60. In the mesa portion 60 of the present example, the structure of the side wall 214 of the trench contact portion 210 is different from that of the example illustrated in FIG. 4. Other structures are similar to those of the example of FIG. 4.

The side wall 214 of the present example includes a first side wall portion 218 and an oblique portion 216. The oblique portion 216 is a portion where its extending direction in the XZ cross section intersects the depth direction (Z axis direction). The oblique portion 216 of the present example and the depth direction intersect at the angle θ1. The side wall 214 of the present example has the oblique portion 216 in at least a part between the first depth position Z1 and the second depth position Z2. The oblique portion 216 may be provided on the entire side surface of the second emitter portion 82. The oblique portion 216 may also be provided on at least a part of a side surface of the third emitter portion 83. The oblique portion 216 of the present example is not provided on the side surface of the first emitter portion 81.

The side wall region 86 is in contact with the oblique portion 216. The side wall region 86 may be in contact with the entire oblique portion 216 in the XZ cross section. An upper end of the side wall region 86 may be in contact with a lower surface of the first emitter portion 81.

The first side wall portion 218 is a region of the side wall 214 of the trench contact portion 210 facing the first emitter portion 81 in the X axis direction. An angle formed between the first side wall portion 218 and the depth direction is smaller than the angle θ1 formed between the oblique portion 216 and the depth direction. The angle formed between the first side wall portion 218 and the depth direction may be less than or equal to half, or ¼, of the angle θ1. The first side wall portion 218 may include a portion parallel to the depth direction. At least half region of the first side wall portion 218 may be parallel to the depth direction, or the entire first side wall portion 218 may be parallel to the depth direction.

By reducing the angle between the first side wall portion 218 and the depth direction, an amount of dopant ions of the p type implanted per unit area of the first side wall portion 218 can be made smaller than that of the oblique portion 216. Therefore, the amount of dopant ions of the p type implanted into an interface between the first emitter portion 81 and the trench contact portion 210 can be reduced, and a decrease in a net doping concentration of the first emitter portion 81 at the interface can be suppressed.

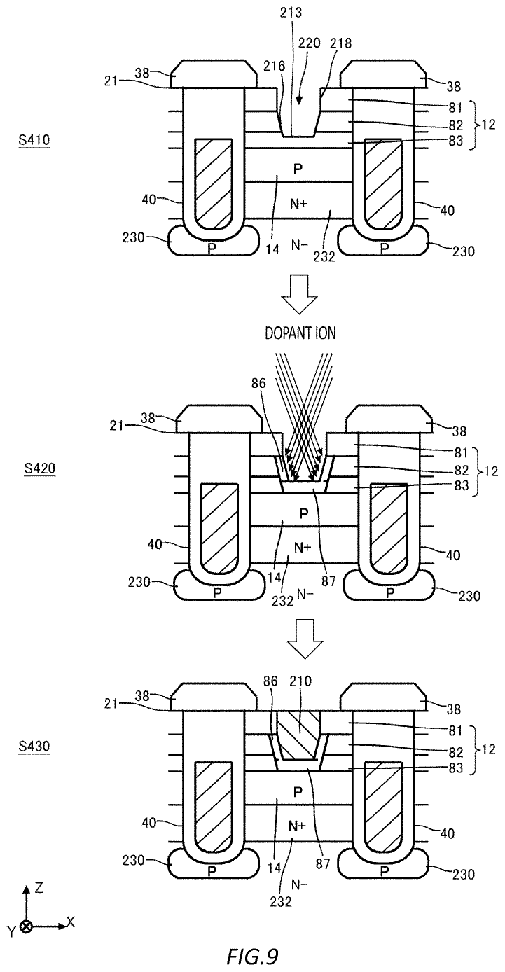

FIG. 9 is a view illustrating a partial process of a manufacturing process of the semiconductor device 100. FIG. 9 illustrates a process of forming the trench contact portion 210, the side wall region 86, and the bottom region 87.

In step S410 of the present example, the gate trench portion 40, the mesa portion 60, the lower end region 230, the accumulation region 232, the interlayer dielectric film 38, the emitter region 12, and the base region 14 are formed in the semiconductor substrate 10. In addition, in S410, a contact trench 220 for forming the trench contact portion 210 is formed in the mesa portion 60. Before the contact trench 220 is formed, each portion of the emitter region 12 may be provided in the entire mesa portion 60 in the X axis direction. In another example, each portion of the emitter region 12 may be formed after the contact trench 220 is formed. In addition, the interlayer dielectric film 38 may be formed after S410, or may be formed after S420.

The contact trench 220 has the first side wall portion 218, an oblique portion, and a bottom surface 213. The bottom surface 213 is a surface including a lower end of the contact trench 220. The bottom surface 213 may be a surface parallel to the XY plane. In another example, the bottom surface 213 may be a portion of a surface of the contact trench 220, a distance from which to the lower end of the contact trench 220 in the Z axis direction is within a predetermined value. The predetermined value may be, for example, 0.1 μm, 0.2 μm, or 0.5 μm.

The oblique portion 216 and the first side wall portion 218 are portions of the surface of the contact trench 220 which extend from the bottom surface 213 to the upper surface 21 of the semiconductor substrate 10. The oblique portion 216 is connected to the bottom surface 213, and the first side wall portion 218 is connected to the upper surface 21. An upper end of the oblique portion 216 is connected to a lower end of the first side wall portion 218. That is, the oblique portion 216 is a lower portion of the side wall of the contact trench 220, and the first side wall portion 218 is an upper portion thereof.

In the present example, at least the oblique portion 216 of the oblique portion 216 or the first side wall portion 218 has an angle with respect to the depth direction. The angle may be the angle θ1 described in FIG. 4 or the like. The first side wall portion 218 may also have an angle with respect to the depth direction. The angle of the first side wall portion 218 may be the same as, smaller than, or larger than the angle of the oblique portion 216. The angle of the first side wall portion 218 in the example of FIG. 9 is smaller than the angle of the oblique portion 216. The first side wall portion 218 may be parallel to the depth direction.

At least a part of the second emitter portion 82 may be exposed on the oblique portion 216. The side surface of the second emitter portion 82, from a lower end to an upper end, may be exposed on the oblique portion 216. That is, the upper end of the oblique portion 216 is arranged at a depth position the same as, or higher than, the upper end of the second emitter portion 82. At least a part of the side surface of the third emitter portion 83 may be exposed on the oblique portion 216.

At least a part of the first emitter portion 81 is exposed on the first side wall portion 218. A lower end of the oblique portion 216 may be arranged at a depth position the same as, or higher than, a lower end of the first emitter portion 81.

In step S420, dopant ions of the p type are implanted into the semiconductor substrate 10 from the upper surface 21 side using the interlayer dielectric film 38 as a mask. Accordingly, dopant ions of the p type are implanted via a side wall or the like of the contact trench 220 that is not covered with the interlayer dielectric film 38. In step S420, dopant ions of the p type are implanted via the contact trench 220 in a state where an angle formed between at least a part of the side wall of the contact trench 220 and an implantation direction of the dopant ions of the p type is not parallel. The angle may be 5 degrees or more, 10 degrees or more, 15 degrees or more, or 20 degrees or more. The angle may be 45 degrees or less, 40 degrees or less, 35 degrees or less, or 30 degrees or less.

For example, in S420, dopant ions are implanted in a state where at least one of the implantation direction of the dopant ions or the extending direction of the oblique portion 216 has an angle with respect to the depth direction. At least a portion (for example, the oblique portion 216) of the side wall of the contact trench 220 may be formed obliquely with respect to the depth direction. As described above, an angle formed between the portion (for example, the oblique portion 216) of the side wall of the contact trench 220 and the depth direction may be 5 degrees or more.

The implantation direction of dopant ions of the p type may be oblique with respect to the depth direction. The angle may be 5 degrees or more, 10 degrees or more, 15 degrees or more, or 20 degrees or more. The angle may be 45 degrees or less, 40 degrees or less, 35 degrees or less, or 30 degrees or less.

In the example of FIG. 9, both the implantation direction of the dopant ions and the extending direction of the oblique portion 216 each have an angle with respect to the depth direction. In another example, when the oblique portion 216 is formed obliquely, the implantation direction of the dopant ions may be parallel to the depth direction. In addition, when the implantation direction of the dopant ions is oblique, the oblique portion 216 may be parallel to the depth direction.

The side wall region 86 is formed by implanting dopant ions of the p type. After the dopant ions of the p type are implanted, the semiconductor substrate 10 may be heat-treated. A p-type dopant concentration in the side wall region 86 after manufacturing the semiconductor device 100 may be higher than an n-type dopant concentration in the second emitter portion 82. In the present example, the region is inverted from the n type to the p type by implanting dopant ions of the p type into the side surface of the second emitter portion 82. Therefore, the p-type dopant concentration in the side wall region 86 is higher than the n-type dopant concentration in the second emitter portion 82. As the concentration of each dopant, for example, a chemical concentration measured by a CEMS method may be used. The p-type dopant concentration in the side wall region 86 may be 2 times or more, 5 times or more, or 10 times or more the n-type dopant concentration in the second emitter portion 82.

The p-type dopant concentration in the side wall region 86 after manufacturing the semiconductor device 100 may be lower than the n-type dopant concentration in the first emitter portion 81. Accordingly, it is possible to prevent the side surface of the first emitter portion 81 from being inverted into the p type. The p-type dopant concentration in the side wall region 86 may be ½ or less, ⅕ or less, 1/10 or less, or 1/100 or less of the n-type dopant concentration in the first emitter portion 81.

The p-type dopant concentration in the side wall region 86 after manufacturing the semiconductor device 100 may be higher than the n-type dopant concentration in the third emitter portion 83. Accordingly, the side surface of the third emitter portion 83 can be inverted from the n type to the p type. The p-type dopant concentration in the side wall region 86 may be 2 times or more, 5 times or more, or 10 times or more the n-type dopant concentration in the third emitter portion 83.

In S420, the bottom region 87 may be formed. The bottom region 87 may be formed together with the side wall region 86 in a same process as the side wall region 86. That is, dopant ions of the p type may be implanted into the bottom region 87 and the side wall region 86 in the same process. In another example, in addition to a first implantation process of implanting dopant ions of the p type into the side wall region 86, a second implantation process of implanting dopant ions of the p type into the bottom region 87 may be provided. The implantation direction in the second implantation process may be smaller in angle with the depth direction than the implantation direction in the first implantation process. That is, the implantation direction in the second implantation process is closer to being perpendicular to the upper surface 21 than the implantation direction in the first implantation process. Accordingly, dopant ions of the p type can be efficiently implanted into the bottom surface 213 of the contact trench 220 in the second implantation process. After manufacturing the semiconductor device 100, the doping concentration of the bottom region 87 may be higher than the doping concentration of the side wall region 86.

In addition, in S420, a dose (/cm²) of the dopant ions implanted into the side wall of the first emitter portion 81 may be smaller than a dose of the dopant ions implanted into the side wall of the second emitter portion 82. For example, by making an angle between the first side wall portion 218 and the implantation direction smaller than an angle between the oblique portion 216 and the implantation direction, it is possible to suppress implantation of dopant ions into the first side wall portion 218. In addition, when the implantation direction of the dopant ions is oblique, by forming a mask for shielding dopant ions on the upper surface 21 in a vicinity of an opening of the contact trench, it is also possible to suppress the implantation of dopant ions into the first side wall portion 218.

In S420, the side wall region 86 may be formed in contact with the oblique portion 216 of the contact trench 220. A position of the side wall region 86 can be adjusted by an implantation depth (acceleration energy) of dopant ions of the p type. The side wall region 86 in contact with the oblique portion 216 can be formed by implanting dopant ions of the p type in a vicinity of a surface of the oblique portion 216.

In step S430, the contact trench 220 is filled with a conductive material to form the trench contact portion 210. The conductive material may be a same material as or a different material from that of the emitter electrode 52. The conductive material may include, for example, tungsten. In addition, a barrier layer including at least one of titanium or titanium nitride may be formed between a metal plug such as tungsten and the semiconductor substrate 10.

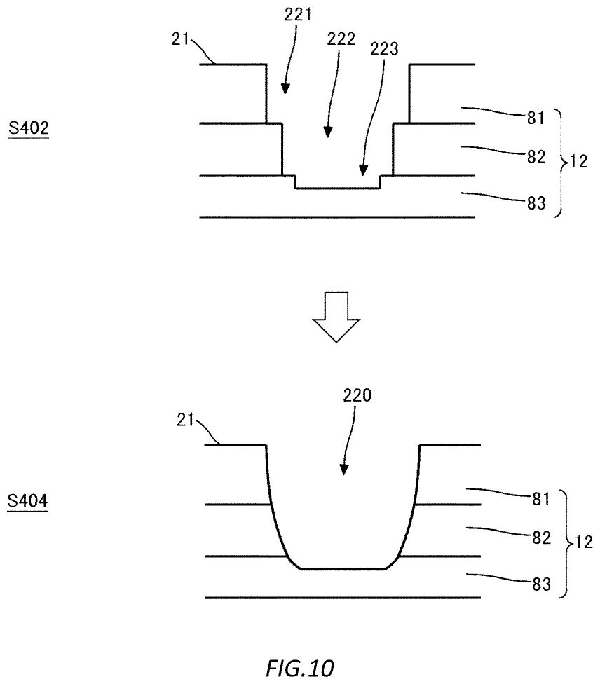

FIG. 10 is a view illustrating an example of a method of forming the contact trench 220. In step S420, a plurality of opening portions 221, 222, and 223, with their opening areas changing stepwise, are formed in the upper surface 21 of the semiconductor substrate 10. Each opening portion may be formed by anisotropic etching. An etching gas in the anisotropic etching is, for example, CHF₃, Cl₂, or BCl₃, but is not limited thereto.

As an example, the opening portion 221 having a largest area is first formed. Next, the opening portion 222 having a second largest area is formed on a bottom surface of the opening portion 221. Next, the opening portion 223 having a third largest area is formed on a bottom surface of the opening portion 222. By such a process, stepped opening portions are formed. A depth position of a lower end of the opening portion 221 may coincide with or be different from a depth position of the lower end of the first emitter portion 81. A depth position of a lower end of the opening portion 222 may coincide with or be different from a depth position of the lower end of the second emitter portion 82. A depth position of a lower end of the opening portion 223 may be arranged inside the third emitter portion 83, may coincide with a depth position of the lower end of the third emitter portion 83, or may be arranged deeper than the lower end of the third emitter portion 83.

In step S404, the stepped opening portions are isotropically etched to form the contact trench 220 having continuous side walls. In S404, the contact trench 220 may be formed by wet etching. A step shape in which an opening area changes discontinuously along the depth direction may or may not remain on the side wall of the contact trench 220. In addition, the plurality of opening portions 221, 222, and 223, with their opening areas changing stepwise, may be used as the contact trench 220 by omitting step S404.

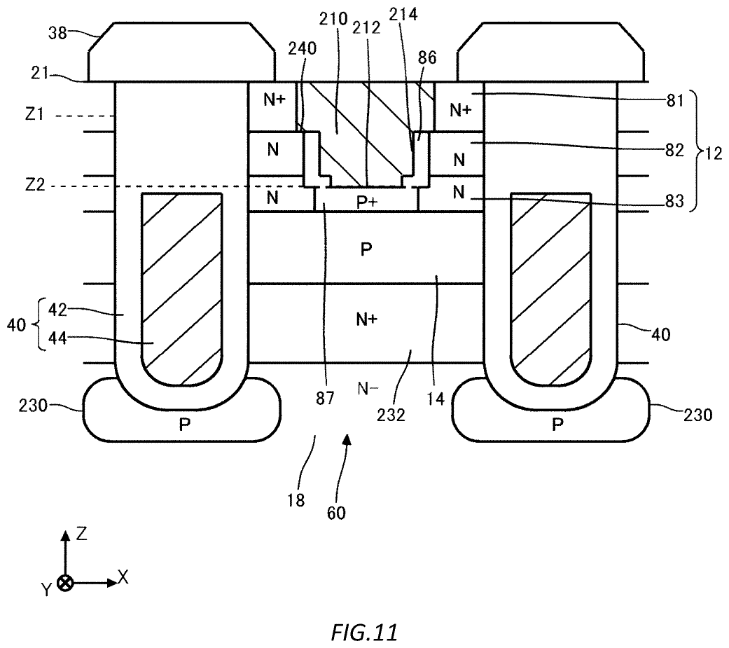

FIG. 11 is a view illustrating another structure example of the mesa portion 60. FIG. 11 is an enlarged view of the cross section in the vicinity of the mesa portion 60. In the mesa portion 60 of the present example, the structure of the side wall 214 of the trench contact portion 210 is different from that of the example illustrated in FIG. 4 or 8. Other structures are similar to those of the example of FIG. 4 or 8.

The side wall 214 of the trench contact portion 210 of the present example includes a step portion 240 in which an inclination of the side wall 214 changes discontinuously between the first depth position Z1 and the second depth position Z2. As described above, a cross-sectional area of the trench contact portion 210 at the first depth position Z1 is larger than a cross-sectional area of the trench contact portion 210 at the second depth position Z2. In the step portion 240, the cross-sectional area of the trench contact portion 210 in the XY plane changes discontinuously along the Z axis direction. The side wall 214 of the trench contact portion 210 may have a surface parallel to the XY plane in the step portion 240. In a portion other than the step portion 240, the side wall 214 may or may not have an angle with respect to the depth direction.

By providing the step portion 240, dopant ions of the p type can be efficiently implanted into an upper surface of the step portion 240. Therefore, the side wall region 86 is easily provided in the region below the step portion 240.

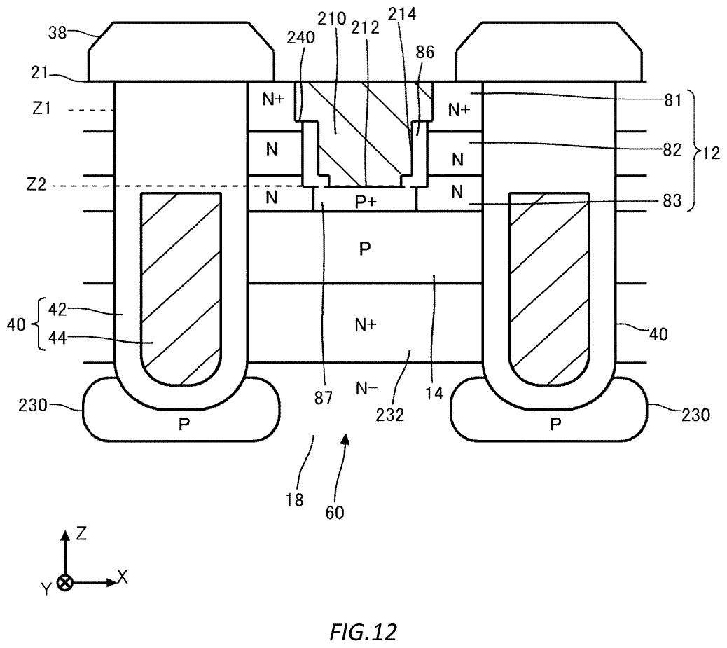

The side wall region 86 may be provided in a portion of the side wall 214 below the step portion 240. The side wall region 86 may be exposed on the upper surface of the step portion 240. The upper surface of the step portion 240 may have a portion where the side wall region 86 is not provided, or the side wall region 86 may be exposed over the entire upper surface. In the example of FIG. 12, the side wall region 86 is not provided in a portion of the side wall 214 above the step portion 240, but the side wall region 86 may be provided in a part of the portion above the step portion 240.

The step portion 240 may be arranged to face the first emitter portion 81 or the second emitter portion 82 in the X axis direction. In the example of FIG. 11, the step portion 240 is arranged to face a boundary between the first emitter portion 81 and the second emitter portion 82 in the X axis direction. In this case, a cross-sectional area of the first emitter portion 81 in the XY plane may be different from a cross-sectional area of the second emitter portion 82 in the XY plane.

The side wall 214 of the trench contact portion 210 may further have a step portion below the second depth position Z2. In the example of FIG. 11, the step portion is provided at a position facing the boundary between the second emitter portion 82 and the third emitter portion 83 in the X axis direction. A depth position of the step portion is not limited to the position.

FIG. 12 is a view illustrating another structure example of the mesa portion 60. FIG. 12 is an enlarged view of the cross section in the vicinity of the mesa portion 60. In the mesa portion 60 of the present example, a position of the step portion 240 is different from that of the example illustrated in FIG. 11. Other structures are similar to those of the example of FIG. 11.

In the example of FIG. 12, the step portion 240 is provided at a position facing the first emitter portion 81 in the X axis direction. In this case, the first emitter portion 81 may also have a step portion. That is, the cross-sectional area of the first emitter portion 81 in the XY plane may change discontinuously at the step portion 240.

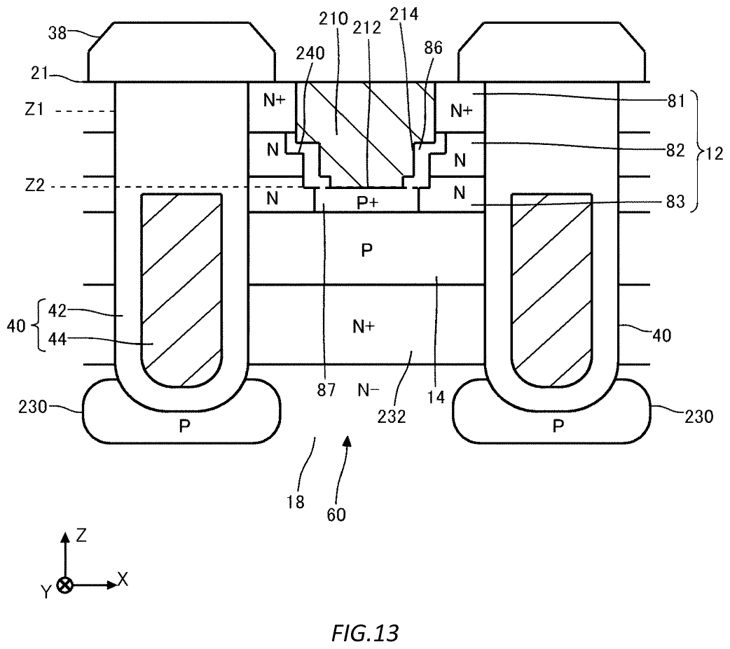

FIG. 13 is a view illustrating another structure example of the mesa portion 60.

FIG. 13 is an enlarged view of the cross section in the vicinity of the mesa portion 60. In the mesa portion 60 of the present example, the position of the step portion 240 is different from that of the example illustrated in FIG. 11. Other structures are similar to those of the example of FIG. 11.

In the example of FIG. 13, the step portion 240 is provided at a position facing the second emitter portion 82 in the X axis direction. In this case, the second emitter portion 82 may also have a step portion. That is, the cross-sectional area of the second emitter portion 82 in the XY plane may change discontinuously at the step portion 240. In addition, the side wall region 86 may be provided on the side surface of the second emitter portion 82 along the step portion 240. That is, the side wall region 86 may also have a step portion.

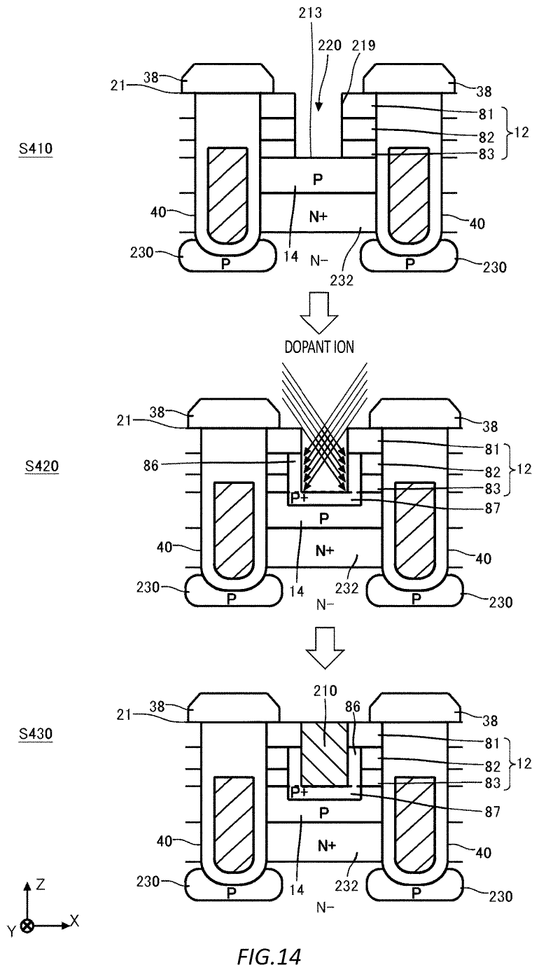

FIG. 14 is a view illustrating another example of steps S410 to S430 of forming the trench contact portion 210, the side wall region 86, and the bottom region 87. In the present example, a shape of the contact trench 220 formed in S410 and the implantation direction of dopant ions of the p type implanted in S420 are different from those of the example of FIG. 9. Others are similar to those of the example of FIG. 9.

Also in the present example, dopant ions of the p type are implanted via the contact trench 220 in a state where an angle formed between at least a part of a side wall 219 of the contact trench 220 and the implantation direction of the dopant ions of the p type is not parallel. However, in step S410 of the present example, the contact trench 220 may be formed such that the side wall 219 extends in a direction parallel to the depth direction at least in a range facing the second emitter portion 82. The entire side wall 219 may extend in the direction parallel to the depth direction.

In step S420 of the present example, dopant ions of the p type are implanted in an implantation direction having an angle with respect to the depth direction. The angle may be 5 degrees or more, 10 degrees or more, 15 degrees or more, or 20 degrees or more. The angle may be 45 degrees or less, 40 degrees or less, 35 degrees or less, or 30 degrees or less. Step S430 of the present example is similar to the example of FIG. 9. Also by such a process, the side wall region 86 can be formed accurately.

In the present example, the side wall 219 is formed in parallel with the depth direction. In another example, the side wall 219 may be formed obliquely such that the cross-sectional area of the contact trench 220 decreases as approaching the upper surface 21. Even in this case, by adjusting the implantation direction of dopant ions of the p type, the implantation direction can be made oblique with respect to the side wall 219, and the side wall region 86 can be formed accurately.

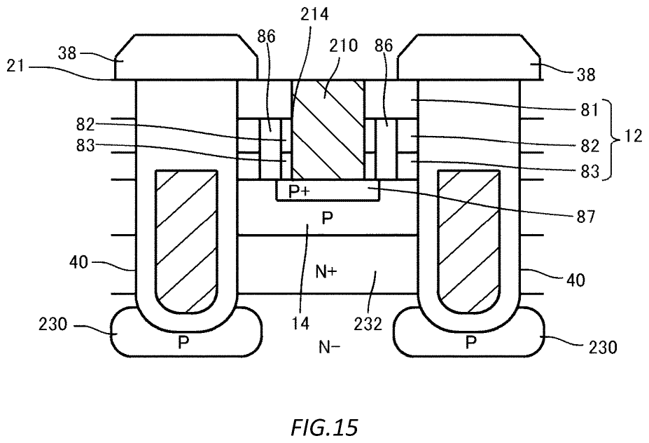

FIG. 15 is a view illustrating another structure example of the mesa portion 60. FIG. 15 is an enlarged view of the cross section in the vicinity of the mesa portion 60. In the mesa portion 60 of the present example, the position of the side wall region 86 is different from that of other examples described in the present specification. Other structures are similar to any of the examples described in the present specification. In the example of FIG. 15, a shape of the trench contact portion 210 is similar to that of the example of FIG. 14, but any example described in the present specification may be applied to the shape of the trench contact portion 210.

The side wall region 86 of the present example is arranged separately from the side wall 214 of the trench contact portion 210. For example, in S420 of FIG. 9 or 14, the side wall region 86 can be formed separately from the side wall 214 of the trench contact portion 210 by increasing acceleration energy of dopant ions of the p type.

The side wall region 86 is provided at least between the trench contact portion 210 and the second emitter portion 82. The side wall region 86 may also be provided between the trench contact portion 210 and the third emitter portion 83. The side wall region 86 of the present example may be provided over the entire second emitter portion 82 and the entire third emitter portion 83 in the depth direction. Since a width of the emitter region 12 between the side wall region 86 and the gate trench portion 40 can be adjusted by adjusting the position of the side wall region 86, a resistance value in the emitter region 12 can be adjusted.

The second emitter portion 82 and the third emitter portion 83 may be provided between the side wall region 86 and the side wall 214. The second emitter portion 82 and the third emitter portion 83 are provided between the side wall region 86 and the gate trench portion 40.

The side wall region 86 may be connected with the bottom region 87. In this case, the emitter region 12 between the side wall region 86 and the side wall 214 is not directly connected with the base region 14. This prevents a current from flowing between the emitter electrode 52 and the base region 14 through the emitter region 12 between the side wall region 86 and the side wall 214.

The side wall region 86 may be arranged on a side close to the side wall 214 between the side wall 214 and the gate trench portion 40. Accordingly, it is possible to suppress the side wall region 86 from being in contact with the gate trench portion 40.

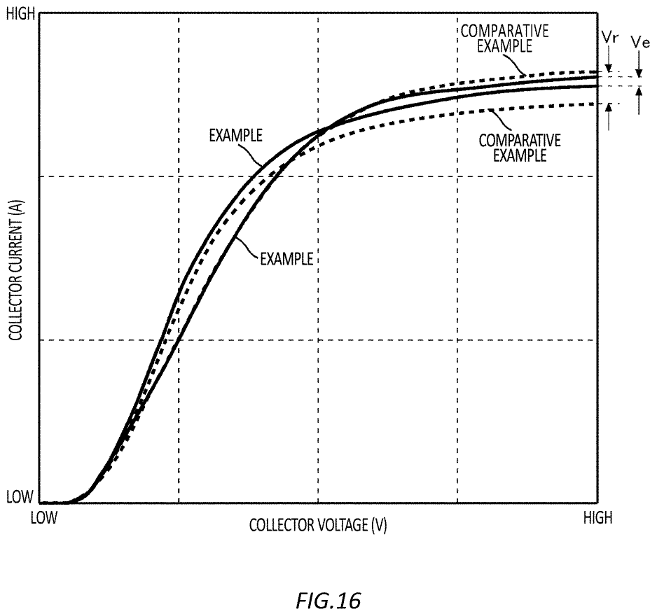

FIG. 16 is a view illustrating an example of collector voltage-collector current characteristics of the semiconductor device 100. FIG. 16 illustrates a plurality of characteristics according to an example in which the side wall region 86 is provided by the method described in FIG. 9 or 14 and a plurality of characteristics according to a comparative example in which the side wall region 86 is provided by another method. In the comparative example, the side wall of the contact trench 220 was formed in parallel with the depth direction, and dopant ions of the p type were implanted in parallel with the depth direction.

In FIG. 16, the characteristics of the comparative example are indicated by broken lines, and the characteristics of the example are indicated by solid lines. As illustrated in FIG. 16, in the comparative example, a variation Vr in the saturation current of the collector current is large. In this regard, in the example, a variation Ve in the saturation current of the collector current is small. In the example, it is considered that the variation in the doping concentration or the like of the side wall region 86 is reduced, and the variation Ve in the saturation current is reduced.

While the present invention has been described above by way of the embodiments, the technical scope of the present invention is not limited to the scope described in the above-described embodiments. It is apparent to persons skilled in the art that various alterations or improvements can be made to the above-described embodiments. It is also apparent from the description of the claims that the embodiments to which such alterations or improvements are made can fall within the technical scope of the present invention.

Each process of the operations, procedures, steps, stages, and the like performed by a device, system, program, and method shown in the claims, the specification, and the drawings can be performed in any order as long as the order is not indicated by “prior to,” “before,” and the like and as long as the output from a previous process is not used in a later process. Even if the operational flow is described using phrases such as “first” or “next” for convenience in the claims, the specification, and the drawings, it does not necessarily mean that the process must be performed in this order.

The present specification and the drawings also disclose inventions according to following items.

### (Item 1)

A semiconductor device which is provided in a semiconductor substrate having an upper surface and a lower surface and including a drift region of a first conductivity type, the semiconductor device including:
a plurality of trench portions which are provided from the upper surface to an inside of the semiconductor substrate;
a mesa portion which is sandwiched between two of the trench portions in the semiconductor substrate;
a trench contact portion which is provided from the upper surface to an inside of the semiconductor substrate in the mesa portion and in which, compared to a cross-sectional area at a first depth position, a cross-sectional area at a second depth position farther from the upper surface than the first depth position is smaller;
a first emitter portion of the first conductivity type which is provided between a side wall of the trench contact portion and the trench portion in the mesa portion;
a second emitter portion of the first conductivity type which is provided below the first emitter portion between the side wall of the trench contact portion and the trench portion and has a doping concentration lower than that of the first emitter portion; and
a side wall region of a second conductivity type which is provided between the side wall of the trench contact portion and the second emitter portion, wherein
the second emitter portion has any one of a flat portion in which a doping concentration distribution in a depth direction is flat, a valley portion in which the doping concentration shows a local minimum value in the depth direction, or a peak in which the doping concentration shows a local maximum value in the depth direction and is lower than that of the first emitter portion.

### (Item 2)

The semiconductor device according to item 1, wherein
the side wall of the trench contact portion includes an oblique portion extending in a direction intersecting the depth direction between the first depth position and the second depth position, and
the side wall region is in contact with the oblique portion.

### (Item 3)

The semiconductor device according to item 2, wherein
an angle formed between the oblique portion and the depth direction is 5 degrees or more.

### (Item 4)

The semiconductor device according to item 2, wherein
the plurality of trench portions are provided side by side in a first direction, and an angle formed between a region of the side wall of the trench contact portion facing the first emitter portion in the first direction and the depth direction is smaller than an angle formed between the oblique portion and the depth direction.

### (Item 5)

The semiconductor device according to item 4, wherein
the region of the side wall of the trench contact portion facing the first emitter portion in the first direction includes a portion parallel to the depth direction.

### (Item 6)

The semiconductor device according to item 1, wherein
the side wall of the trench contact portion includes a step portion in which an inclination of the side wall changes discontinuously between the first depth position and the second depth position.

### (Item 7)

The semiconductor device according to item 6, wherein
the plurality of trench portions are provided side by side in a first direction, and
the step portion is arranged to face the first emitter portion or the second emitter portion in the first direction.

### (Item 8)

The semiconductor device according to item 7, wherein
the step portion is arranged to face the second emitter portion in the first direction.

### (Item 9)

The semiconductor device according to item 7, wherein
the step portion is arranged to face a boundary between the first emitter portion and the second emitter portion in the first direction.

### (Item 10)

The semiconductor device according to item 1, wherein
the plurality of trench portions are provided side by side in a first direction, and
the first emitter portion includes a region that does not face the side wall region in the first direction.

### (Item 11)

The semiconductor device according to item 10, wherein
the first emitter portion is in contact with the side wall of the trench contact portion.

### (Item 12)

The semiconductor device according to any one of items 1 to 11, wherein
the side wall region is in contact with the side wall of the trench contact portion.

### (Item 13)

The semiconductor device according to any one of items 1 to 11, wherein
the side wall region is separated from the side wall of the trench contact portion.

### (Item 14)

The semiconductor device according to any one of items 1 to 11, wherein
a p-type dopant concentration in the side wall region is higher than an n-type dopant concentration in the second emitter portion.

### (Item 15)

The semiconductor device according to any one of items 1 to 11, wherein
a p-type dopant concentration in the side wall region is lower than an n-type dopant concentration in the first emitter portion.

### (Item 16)

The semiconductor device according to any one of items 1 to 11, further including
a third emitter portion of the first conductivity type which is provided below the second emitter portion between the side wall of the trench contact portion and the trench portion and has a doping concentration higher than that of the second emitter portion.

### (Item 17)

The semiconductor device according to item 16, wherein
the side wall region is also provided between the side wall of the trench contact portion and the third emitter portion.

### (Item 18)

The semiconductor device according to item 16, wherein
a p-type dopant concentration in the side wall region is higher than an n-type dopant concentration in the third emitter portion.

### (Item 19)

The semiconductor device according to any one of items 1 to 11, wherein
the semiconductor substrate is a wide band gap substrate formed of a material having a band gap larger than that of silicon.

### (Item 20)

A semiconductor device which is provided in a semiconductor substrate having an upper surface and a lower surface and including a drift region of a first conductivity type, the semiconductor device including:
a plurality of trench portions which are provided from the upper surface to an inside of the semiconductor substrate;
a mesa portion which is sandwiched between two of the trench portions in the semiconductor substrate;
a trench contact portion which is provided from the upper surface to an inside of the semiconductor substrate in the mesa portion;
a first emitter portion of the first conductivity type which is provided between a side wall of the trench contact portion and the trench portion in the mesa portion;
a second emitter portion of the first conductivity type which is provided below the first emitter portion between the side wall of the trench contact portion and the trench portion and has a doping concentration lower than that of the first emitter portion; and
a side wall region of a second conductivity type which is provided separately from the side wall between the side wall of the trench contact portion and the trench portion, wherein
the second emitter portion has any one of a flat portion in which a doping concentration distribution in a depth direction is flat, a valley portion in which the doping concentration shows a local minimum value in the depth direction, or a peak in which the doping concentration shows a local maximum value in the depth direction and is lower than that of the first emitter portion.

### (Item 21)

The semiconductor device according to item 20, wherein
the side wall region is provided between the trench contact portion and the second emitter portion.

### (Item 22)

The semiconductor device according to item 21, further including
a third emitter portion of the first conductivity type which is provided below the second emitter portion between the side wall of the trench contact portion and the trench portion and has a doping concentration higher than that of the second emitter portion, wherein
the side wall region is also provided between the side wall of the trench contact portion and the third emitter portion.

### (Item 23)

The semiconductor device according to item 22, wherein
the first emitter portion is in contact with the side wall of the trench contact portion.

### (Item 24)

A manufacturing method of a semiconductor device which is provided in a semiconductor substrate having an upper surface and a lower surface and including a drift region of a first conductivity type, wherein
the semiconductor device includes a plurality of trench portions which are provided from the upper surface to an inside of the semiconductor substrate, a mesa portion which is sandwiched between two of the trench portions in the semiconductor substrate, a trench contact portion which is provided from the upper surface to an inside of the semiconductor substrate in the mesa portion, a first emitter portion of the first conductivity type which is provided between a side wall of the trench contact portion and the trench portion in the mesa portion, a second emitter portion of the first conductivity type which is provided below the first emitter portion between the side wall of the trench contact portion and the trench portion and has a doping concentration lower than that of the first emitter portion, and a side wall region of a second conductivity type which is provided between the side wall of the trench contact portion and the second emitter portion,
the manufacturing method includes:
forming a contact trench for forming the trench contact portion in the mesa portion; and
forming the side wall region by implanting a dopant of the second conductivity type via the contact trench in a state where an angle formed between a side wall of the contact trench and an implantation direction of the dopant is not parallel.

### (Item 25)

The manufacturing method according to item 24, wherein
at least a portion of the side wall of the contact trench is formed obliquely with respect to a depth direction.

### (Item 26)

The manufacturing method according to item 25, wherein
an angle formed between the portion of the side wall of the contact trench and the depth direction is 5 degrees or more.

### (Item 27)

The manufacturing method according to item 24, wherein
the implantation direction of the dopant is oblique with respect to a depth direction.
   (Item 28) The manufacturing method according to item 27, wherein
an angle formed between the implantation direction of the dopant and the depth direction is 5 degrees or more.

### (Item 29)

The manufacturing method according to any one of items 24 to 28, wherein
the side wall region is formed in contact with the side wall of the contact trench.

### (Item 30)

The manufacturing method according to any one of items 24 to 28, wherein
the side wall region is formed separately from the side wall of the contact trench.

What is claimed is:

1. A semiconductor device which is provided in a semiconductor substrate having an upper surface and a lower surface and including a drift region of a first conductivity type, the semiconductor device comprising:
a plurality of trench portions which are provided from the upper surface to an inside of the semiconductor substrate;
a mesa portion which is sandwiched between two of the trench portions in the semiconductor substrate;
a trench contact portion which is provided from the upper surface to an inside of the semiconductor substrate in the mesa portion and in which, compared to a cross-sectional area at a first depth position, a cross-sectional area at a second depth position farther from the upper surface than the first depth position is smaller;
a first emitter portion of the first conductivity type which is provided between a side wall of the trench contact portion and the trench portion in the mesa portion;
a second emitter portion of the first conductivity type which is provided below the first emitter portion between the side wall of the trench contact portion and the trench portion and has a doping concentration lower than that of the first emitter portion; and
a side wall region of a second conductivity type which is provided between the side wall of the trench contact portion and the second emitter portion, wherein
the second emitter portion has any one of a flat portion in which a doping concentration distribution in a depth direction is flat, a valley portion in which the doping concentration shows a local minimum value in the depth direction, or a peak in which the doping concentration shows a local maximum value in the depth direction and is lower than that of the first emitter portion.

2. The semiconductor device according to claim 1, wherein
the side wall of the trench contact portion includes an oblique portion extending in a direction intersecting the depth direction between the first depth position and the second depth position, and
the side wall region is in contact with the oblique portion.

3. The semiconductor device according to claim 2, wherein
the plurality of trench portions are provided side by side in a first direction, and
an angle formed between a region of the side wall of the trench contact portion facing the first emitter portion in the first direction and the depth direction is smaller than an angle formed between the oblique portion and the depth direction.

4. The semiconductor device according to claim 3, wherein
the region of the side wall of the trench contact portion facing the first emitter portion in the first direction includes a portion parallel to the depth direction.

5. The semiconductor device according to claim 1, wherein
the side wall of the trench contact portion includes a step portion in which an inclination of the side wall changes discontinuously between the first depth position and the second depth position.

6. The semiconductor device according to claim 5, wherein
the plurality of trench portions are provided side by side in a first direction, and
the step portion is arranged to face the first emitter portion or the second emitter portion in the first direction.

7. The semiconductor device according to claim 1, wherein
the plurality of trench portions are provided side by side in a first direction, and
the first emitter portion includes a region that does not face the side wall region in the first direction.

8. The semiconductor device according to claim 7, wherein
the first emitter portion is in contact with the side wall of the trench contact portion.

9. The semiconductor device according to claim 1, wherein
the side wall region is in contact with the side wall of the trench contact portion.

10. The semiconductor device according to claim 1, wherein
the side wall region is separated from the side wall of the trench contact portion.

11. The semiconductor device according to claim 1, wherein
a p-type dopant concentration in the side wall region is higher than an n-type dopant concentration in the second emitter portion.

12. The semiconductor device according to claim 1, wherein
a p-type dopant concentration in the side wall region is lower than an n-type dopant concentration in the first emitter portion.

13. The semiconductor device according to claim 1, further comprising
a third emitter portion of the first conductivity type which is provided below the second emitter portion between the side wall of the trench contact portion and the trench portion and has a doping concentration higher than that of the second emitter portion.

14. The semiconductor device according to claim 13, wherein
the side wall region is also provided between the side wall of the trench contact portion and the third emitter portion.

15. A semiconductor device which is provided in a semiconductor substrate having an upper surface and a lower surface and including a drift region of a first conductivity type, the semiconductor device comprising:
a plurality of trench portions which are provided from the upper surface to an inside of the semiconductor substrate;
a mesa portion which is sandwiched between two of the trench portions in the semiconductor substrate;
a trench contact portion which is provided from the upper surface to an inside of the semiconductor substrate in the mesa portion;
a first emitter portion of the first conductivity type which is provided between a side wall of the trench contact portion and the trench portion in the mesa portion;
a second emitter portion of the first conductivity type which is provided below the first emitter portion between the side wall of the trench contact portion and the trench portion and has a doping concentration lower than that of the first emitter portion; and
a side wall region of a second conductivity type which is provided separately from the side wall between the side wall of the trench contact portion and the trench portion, wherein
the second emitter portion has any one of a flat portion in which a doping concentration distribution in a depth direction is flat, a valley portion in which the doping concentration shows a local minimum value in the depth direction, or a peak in which the doping concentration shows a local maximum value in the depth direction and is lower than that of the first emitter portion.

16. The semiconductor device according to claim 15, wherein
the side wall region is provided between the trench contact portion and the second emitter portion.

17. The semiconductor device according to claim 16, further comprising
a third emitter portion of the first conductivity type which is provided below the second emitter portion between the side wall of the trench contact portion and the trench portion and has a doping concentration higher than that of the second emitter portion, wherein
the side wall region is also provided between the side wall of the trench contact portion and the third emitter portion.

18. The semiconductor device according to claim 17, wherein
the first emitter portion is in contact with the side wall of the trench contact portion.

19. A manufacturing method of a semiconductor device which is provided in a semiconductor substrate having an upper surface and a lower surface and including a drift region of a first conductivity type, wherein
the semiconductor device includes a plurality of trench portions which are provided from the upper surface to an inside of the semiconductor substrate, a mesa portion which is sandwiched between two of the trench portions in the semiconductor substrate, a trench contact portion which is provided from the upper surface to an inside of the semiconductor substrate in the mesa portion, a first emitter portion of the first conductivity type which is provided between a side wall of the trench contact portion and the trench portion in the mesa portion, a second emitter portion of the first conductivity type which is provided below the first emitter portion between the side wall of the trench contact portion and the trench portion and has a doping concentration lower than that of the first emitter portion, and a side wall region of a second conductivity type which is provided between the side wall of the trench contact portion and the second emitter portion,
the manufacturing method comprises:
forming a contact trench for forming the trench contact portion in the mesa portion; and
forming the side wall region by implanting a dopant of the second conductivity type via the contact trench in a state where an angle formed between a side wall of the contact trench and an implantation direction of the dopant is not parallel.

20. The manufacturing method according to claim 19, wherein
the implantation direction of the dopant is oblique with respect to a depth direction.
